(19) United States
(12) Patent Application Publication
(10) Pub. No.: US 2015/0311815 A1
(43) Pub. Date: Oct. 29, 2015

(54) HERMETIC HIGH CURRENT SOLID STATE POWER CONTROLLER

(71) Applicant: Parker-Hannifin Corporation, Cleveland, OH (US)

(72) Inventors: Velimir NEDIC, Huntington Beach, CA (US); Robert S. BENWARD, Huntington Station, NY (US); William D. HENRY, Wyandanch, NY (US)

(21) Appl. No.: 14/697,088

(22) Filed: Apr. 27, 2015

Related U.S. Application Data
(60) Provisional application No. 61/984,161, filed on Apr. 25, 2014.

(51) Int. Cl. H02M 7/00; H02M 7/539; H05K 5/00; H02M 3/335; H05K 1/18; H05K 1/03

(52) U.S. Cl. CPC H02M 7/003; H05K 1/181; H05K 1/0306; H05K 5/0095; H02M 3/33507; H02M 7/539; H05K 2201/10166

(57) ABSTRACT

A solid state power controller (SSPC) includes a support structure, and a first solid state power switch die arranged relative to the support structure, the solid state power switch die including a solid state power switch having an input terminal for connecting to a power source and an output terminal for providing power to an electrical component. A first gate driver is electrically coupled to the first solid state power switch die, and a control module is operatively coupled to the first gate driver. A hermetic enclosure surrounds at least the first solid state power switch die.

### RELATED APPLICATION DATA

This application claims priority of U.S. Provisional Application No. 61/984,161 filed on Apr. 25, 2014, which is incorporated herein by reference in its entirety.

### FIELD OF INVENTION

The present invention relates generally to power controllers, and more particularly to a hermetic high-current solid state power controller for use in aircraft.

### BACKGROUND

Aircraft and propulsion (gas turbine engines) power system architecture has been heading for major changes. A dominant trend in advanced aircraft power systems is increasing use of electric power to drive aircraft and propulsion subsystems that, in a conventional aircraft, have been driven by a combination of mechanical, electrical, hydraulic, and pneumatic systems. The trend is to replace more engine-driven mechanical, hydraulic, and pneumatic loads with electrical loads due to performance and reliability issues.

Advances in the areas of power electronics, electric drives, and control electronics are already providing momentum to improve the performance of aircraft electrical systems and their reliability. Electrical subsystems require lower engine power, operate with higher efficiency, and can be used on an as needed basis.

Latest generation aircraft power systems require power electronic controls which are generally used to perform three different tasks. The first task is power distribution, e.g., on/off switching of loads, which conventionally has been performed by mechanical switches, circuit breakers and/or relays. The second task is power control, e.g., controlling electric machines for fuel, hydraulic, and actuation systems, which conventionally has been performed using a combination of mechanical, electrical, pneumatic and hydraulic systems. The third task is power conversion, e.g., changing system voltage to a higher or lower level, and/or converting electrical power from one form to another using DC/DC, DC/AC, and AC/DC converters, which conventionally has been performed using silicon-based technology.

### SUMMARY OF INVENTION

Current state-of-the art solid state power controller (SSPC) technology uses solid-state MOSFET switches offering low on resistance, low voltage drop, high off impedance, low power dissipation and high leakage at elevated temperatures. Drawbacks of conventional silicon-based high-voltage SSPC technology, however, include the power consumption, size and/or footprint required by such controllers. More specifically, conventional SSPC technology generates significant heat, and conventional packaging for such SSPCs requires use of relatively large heat dissipating means, e.g., large heat sinks. Further, it is difficult to use conventional SSPCs in combination to form a larger-rated device while still maintaining an insulated environment for the combined SSPCs.

The present disclosure provides an SSPC for use in aircraft power distribution systems, power control systems and power conversion systems that requires less space than conventional SSPCs. Further, the SSPC in accordance with the present disclosure enables multiple SSPCs to be combined to provide a higher power rating, while at the same time providing such combination in a hermetically-sealed environment. By replacing conventional components such mechanical switches, relays, circuit breakers, motors, pumps, etc. with SSPCs, considerable weight savings can be achieved while providing greater flexibility and reliability. Further, SSPC technology provides reliable wide temperature operation as required by the latest generation aircraft power systems.

In addition, software features such as arc fault protection enable the SSPC to detect hazardous low current arcs that, if left undetected, could start a fire on the aircraft and/or damage aircraft wiring and components. Further features such as Prognostics Health Management (PHM), which can be implemented by detecting weakened performance parameters indicative of an impending semiconductor die failure, enable the SSPC to alert maintenance personal of the potential failure.

According to one aspect of the invention, a solid state power controller (SSPC) includes: a substrate having a plurality of regions, at least some of the plurality of regions being hermetic; a first solid state power switch die attached directly to at least one of the hermetic regions of the substrate, the solid state power switch die including a solid state power switch having an input terminal for connecting to a power source and an output terminal for providing power to an electrical component; and a first hermetic enclosure surrounding at least the first solid state power switch die.

According to one aspect of the invention, the first hermetic enclosure is arranged directly on the first solid state power switch die.

According to one aspect of the invention, the SSPC includes: a first gate driver electrically coupled to the first solid state power switch die; and a control module operatively coupled to the first gate driver.

According to one aspect of the invention, the SSPC includes: a second solid state power switch die attached directly to hermetic portions of the substrate; and a second hermetic enclosure surrounding at least the second solid state power switch die.

According to one aspect of the invention, the second hermetic enclosure is arranged directly on the second solid state power switch die.

According to one aspect of the invention, the SSPC includes: a second gate driver coupled to the second solid state power switch die.

According to one aspect of the invention, the SSPC includes an input/output module operatively coupled to the control module.

According to one aspect of the invention, the SSPC includes a DC-DC converter operative to provide isolated power to the control module.

According to one aspect of the invention, the die comprises a silicon carbide transistor.

According to one aspect of the invention, the SSPC includes the silicon carbide transistor comprises one of a metal oxide semiconductor field effect transistor (MOSFET), a junction gate field effect transistor (JFET) or a bipolar junction transistor (BJT).

According to one aspect of the invention, the JFET comprises a vertical JFET (VJFET).

According to one aspect of the invention, the hermetic enclosure comprises monometallic wire bonds.

According to one aspect of the invention, the hermetic enclosure comprises low coefficient of thermal expansion (CTE) materials.

According to one aspect of the invention, the substrate comprises a ceramic material.

According to one aspect of the invention, the substrate comprises alumina.

According to one aspect of the invention, the hermetic enclosure comprises copper-molybdenum.

According to one aspect of the invention, the SSPC includes electrodes electrically connected to the first solid state power switch die, the electrodes comprising copper-molybdenum.

According to one aspect of the invention, the first die further comprises a communication interface operative to transfer data to and receive data from another device.

According to one aspect of the invention, the first solid state power switch die includes a first pole for coupling to a power source and a second pole for selectively providing power from the power source to an electric device, and the SSPC includes a first sense interface having an input and an output, the input of the first sense interface electrically connected to second pole of the first solid state power switch, and the output of the first sense interface electrically connected to the control module.

According to one aspect of the invention, the first sense interface is arranged over the support structure.

According to one aspect of the invention, a power distribution system includes: a power source; and a plurality of SSPC's as described herein, each SSPC electrically connected to the power source to selectively provide power to the respective output terminal.

According to one aspect of the invention, a DC-DC converter includes: first and second input terminals for receiving a DC voltage; first and second output terminals for outputting a DC voltage; a transformer having a primary winding and a secondary winding, the primary winding electrically connected to the first and second input terminals, and the secondary winding electrically connected to the first and second output terminals; an SSPC as described herein electrically connected to the primary winding; and a controller operatively coupled to the SSPC, the controller operative to selectively enable and disable the SSPC to selectively apply current to the primary winding.

According to one aspect of the invention, an inverter for providing an AC output voltage includes: first and second input terminals for receiving a DC voltage; a plurality of output terminals for outputting an AC voltage; a plurality of

SSPCs as described herein, wherein a solid state power switch of a first SSPC of the plurality of SSPCs is electrically in series with a solid state power switch of a second SSPC of the plurality of SSPCs, the connection between the respective solid state power switches electrically connected to one of the plurality of output terminals, and wherein the series connected SSPCs are electrically connected to the first and second input terminals; and a controller operatively coupled to the plurality of SSPCs, the controller configured to selectively switch the plurality of SSPCs to provide an AC output at the plurality of output terminals.

The foregoing and other features of the invention are hereinafter described in greater detail with reference to the accompanying drawings.

### BRIEF DESCRIPTION OF THE DRAWINGS

FIG. 1 is a schematic representation of a solid state power controller in accordance with the present disclosure.

FIG. 2A is a perspective view of an exemplary solid state power controller in accordance with the present disclosure.

FIG. 2B is a perspective view of another exemplary solid state power controller in accordance with the present disclosure.

FIG. 3 is a schematic diagram of a power distribution system using the solid state power controller in accordance with the present disclosure.

FIG. 4 is a schematic diagram of a power conversion system using the solid state power controller in accordance with the present disclosure.

FIG. 5 is a schematic diagram of a power control system using the solid state power controller in accordance with the present disclosure.

FIG. 6 is a schematic diagram of a conventional snubber circuit.

FIG. 7 is a schematic diagram of an active voltage clamp that can be used with the solid state power controller.

FIG. 8 is a graph showing voltage waveforms for the active voltage clamp of FIG. 7.

### DETAILED DESCRIPTION

Inventive aspects in accordance with the present disclosure will be described in the context of aircraft power systems, including power distribution, power control and power conversion. It should be appreciated, however, that aspects in accordance with the present disclosure are not limited to aircraft power systems, but also can be applied to power systems in ships, submarines and the like, and/or in systems where available space is limited and/or where future expansion is contemplated.

SSPCs are electronic circuit breakers and, as such, do not suffer from limiting characteristic of electro-mechanical contactors, such as restricted temperature range, contact degradation (lifetime), and slow response/switching times. A silicon carbide (SiC) based hermetic SSPC in accordance with the present disclosure brings together significant advancements in semiconductor devices and semiconductor packaging and has the potential to bring advanced features far beyond typical contactor-based distribution units used in aircraft. SiC can operate at junction temperature of 200 degrees C. or above in order to deliver and dissipate power. Operation of a SiC device at higher junction temperatures than its silicon (Si) counterpart allows overall system weight reduction by reducing the thermal requirements (thus allowing smaller heat sinks to be utilized) and increasing the reliability of operation at lower temperatures. In addition, a larger band gap combined with higher electric field strength allow SiC devices to have a significant improvement in on-resistance for a given breakdown voltage.

The SSPC in accordance with the present disclosure can achieve single channel currents of 120 Amperes (A) continuous and 400 A peak. Potential advantages include greater temperature operating range, significant increase in lifetime cycles, significant increase in switching speeds (on/off times), the detection and management of arc faults, and potentially eliminating special arrangements that have been necessary in order to handle the closure of capacitive loads.

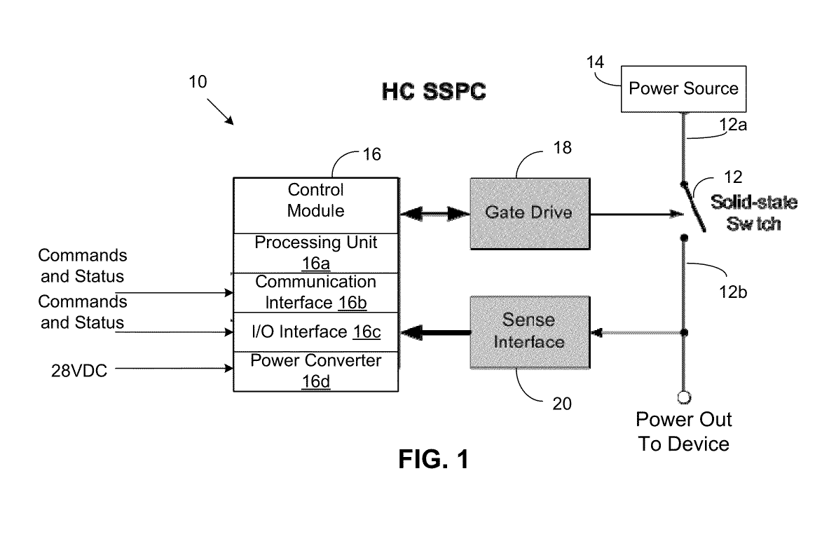

With reference to FIG. 1, an exemplary SSPC 10 in accordance with the present disclosure is schematically illustrated. The SSPC 10 includes one or more solid state power switches (SSPS) 12 each having a first pole 12a and a second pole 12b. When used, for example, in power distribution, the first pole 12a may be connected to a power source 14 and the second pole 12b may be connected to an electronic device (not shown). As will be appreciated, other applications may have other connections to the first and second poles of the SSPC. Normal operation of the SSPS 12 includes two different states. In a first state (the OFF state) the first pole 12a is electrically disconnected from the second pole 12b and thus the flow of current between the first pole and the second pole is inhibited. In a second state the first pole 12a is electrically connected to the second pole 12b (the ON state) thus enabling current flow between the poles. By controlling the state of the SSPS 12, power can be selectively provided to the electronic device.

To control the state of the SSPS 12, the SSPC 10 also includes a control module 16. In one embodiment the SSPC 10 includes a single control module 16 configured to control a plurality of SSPSs 12. In another embodiment, each SSPS 12 may have its own dedicated control module 16. The control module 16 may include a processing unit 16a, such as a processor and memory that executes code stored in the memory, or an ASIC configured to carry out the functions of the SSPC 10.

The control module 16 may control the state of the SSPS 12 based on commands received from other electronic devices. For example, a central control unit (not shown) may be communicatively coupled to the control module 16 via a communication interface 16b. In one embodiment, the communication interface 16b is based on the CAN bus standard. Based on the requirements of the system, the central control unit, via the communications interface 16b, can command the control module 16 to enable/disable one or more SSPSs 12. Alternatively, the control module 16 may receive commands from user-operated devices, such as a switch, e.g., an ON/OFF switch (not shown). The switch status can be communicated to the control module 16 via an I/O interface 16c, which may be isolated and level shifted via optical isolation from both a power side and an external controller.

Further, the control module 16 may include a power converter 16d for converting and isolating incoming power for use within the SSPC 10. For example, aircraft power may be 28 VDC, which may not suitable for use with conventional integrated circuits. The power converter 16d may include DC-DC converters that can convert the 28VDC power to 5VDC, for example, so as to provide isolated power to the control and power circuitry.

While the communication module 16b, I/O module 16c and power converter 16d are shown as being integrated within the control module 16, one or more of the devices may be separate “stand alone” modules communicatively coupled to the control module 16.

The SSPC 10 also includes a gate drive 18 having a first terminal operatively connected to a gate of the SSPS 12 and a second terminal operatively connected to the control module 16. The gate drive 18 is configured to convert a low-power input received from the control module 16 to a high-current drive output for application to the gate of the SSPS 12. In this manner, the control module 16 can control the ON/OFF state of the SSPS 12.

The SSPC 10 may further include a sense interface 20 having a first terminal operatively coupled to the second pole 12b of the SSPS 12 and a second terminal operative coupled to the control module 16. The sense interface 20 monitors a status of the SSPS 12, for example, by detecting if power is present at the second pole 12b. The sense interface 20 provides the status of the SSPS 12 to the control module 16, which can use the information to determine if the SSPS 12 is operating properly. For example, the control module 16 may compare a command provided to the gate drive 18 with the SSPS status as sensed by the sense driver 20. If the sensed status does not agree with the command, it can be concluded that the SSPS 12 is not operating normally and a fault may be generated.

In addition to controlling and monitoring the state of each SSPS 12, the control module 16 performs various other tasks such as, for example, monitoring the overload status of the SSPS 12, predictive fault detection, arc fault detection, etc. For example, the control module 16 may monitor the current passing through the SSPS 12. If the current exceeds a maximum safe continuous range but is less than an absolute maximum limit, the control module 16 may allow such operation for a predetermined time period. However, if the current exceeds the absolute maximum limit, the control module 16 may immediately disable the SSPS 12.

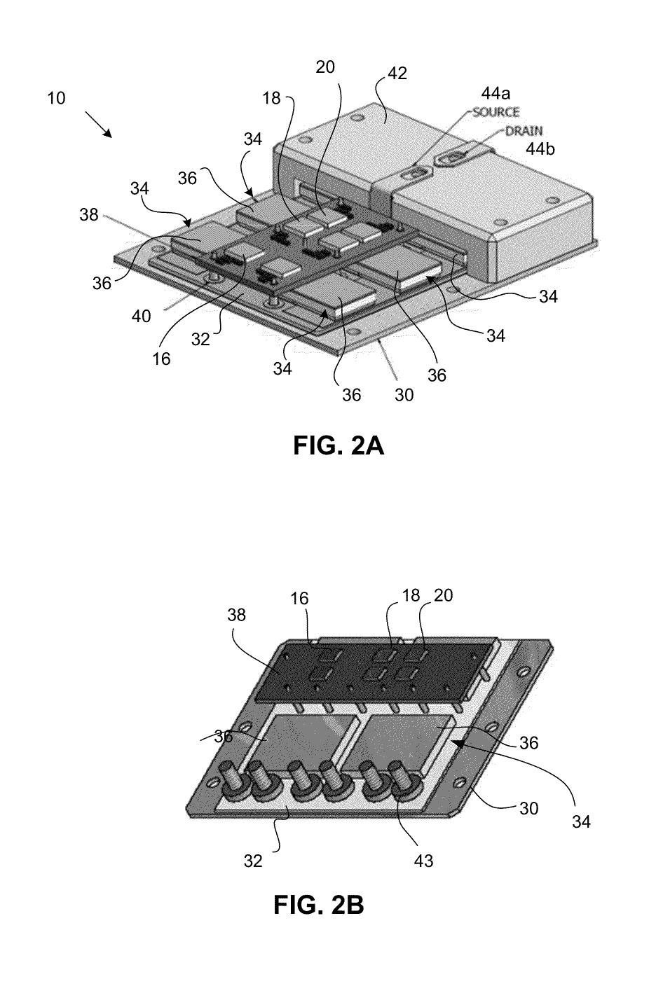

With additional reference to FIG. 2A, a perspective view of an exemplary SSPC 10 in accordance with the present disclosure is shown. The exemplary SSPC 10 includes a base 30 that facilitates mounting the SSPC 10 to a support structure, heat sink, etc. Preferably the base 30 is formed from a material that is thermally efficient. In one embodiment, the base is formed from copper. In another embodiment, the base is formed from aluminum. The base 30 can optionally be supplied with through holes 31 for standard mounting hardware, e.g., a fastener such as a screw or bolt. For example, the base 30 may be fastened to a heatsink via a plurality of screws.

The SSPC 10 also includes a hermetic substrate 32 (also referred to as a support structure) having a plurality of regions, at least portions of which are hermetic so as to provide an air-tight surface. The hermetic substrate 32 may be attached to the base 30, for example, via a fastener, such as an adhesive, a screw, a nut and bolt, etc. In one embodiment the hermetic substrate 32 comprises a ceramic material. In one embodiment the hermetic substrate 32 comprises alumina.

A plurality of SSPS dies 34 are attached directly to the hermetic regions of the substrate 32 using, for example, a thermally conductive adhesive, and a hermetic structure 36 is formed directly on and around each SSPS die 34 (in FIG. 2 the dies are arranged within the hermetic structure 36 and thus cannot be seen—reference number 34 generally refers to the dies inside the structure 36).

By placing the dies 34 directly on the hermetic substrate 32 and directly forming the structure 36 around the dies, at least one thermal layer (which contributes to temperature rise) is eliminated from the device. As a result, heat can more readily be removed from the dies 34 thereby enabling them to run at lower junction temperatures while still providing a hermetic environment.

Each die 34 includes a solid state power switch 12 having an input terminal (a first pole 12a) and an output terminal (a second pole 12b). Each SSPS die 30 may include a silicon carbide transistor, which may be in the form of a metal oxide semiconductor field effect transistor (MOSFET), a bipolar junction transistor (BJT), or a junction gate field effect transistor (JFET). When embodied as a JFET, the JFET may be configured as a vertical JFET (VJFET).

The hermetic structure 36 in combination with the hermetic portion of the substrate 32 form a hermetic enclosure that seals and protects the SSPS die 30 from the ambient environment, provides rugged ceramic construction, is light weight and low cost compared to conventional through-hole device such as TO-254 packaging. In one embodiment, the hermetic structure comprises copper-molybdenum, and may include monometallic wire bonds. Preferably, the hermetic structure 36 does not utilize soft solders for attachment to the die or for sealing to the hermetic substrate 32, and does not incorporate glass seals. The hermetic structure 36 preferably includes low coefficient of thermal expansion (CTE) materials.

A control board 38 is arranged over the hermetic structure 36 and is attached to the substrate 32, for example, via standoffs (not shown). Mounted on the control board 38 are one or more control modules 16, gate drives 18 and sense interfaces 20 as described herein. The gate drive 18 and sense interface 20 may be coupled to the control module 16 via one or more busses, control lines, etc. formed as traces on the control board.

Connection means 40, such as pins, are electrically connected to the SSPS 12 of each die 34, and to a respective gate driver 18 or sense interface 20 via traces formed on the control board 38. While for sake of clarity only several connection means 40 are shown in FIG. 2, it will be appreciated that the number of connection means corresponds to the number of SSPSs. For example, for each SSPS 12 there may be a connection means 40 corresponding to the gate, source, and drain (or base, collector and emitter for a BJT) of the SSPS 12.

A support structure 42 may be formed over the hermetic structure 36 and control board 38 to provide mechanical support for power terminals 44a and 44b, which may be coupled to the first and second poles 12a and 12b, respectively of the SSPS 12. The power terminals may be formed, for example, from copper-molybdenum electrodes. The support structure 42 can facilitate attachment of the SSPC 10 to bus bar or large gauge wire so as to prevent application of undue mechanical stress to the relatively delicate components of the SSPC 10. This is particularly advantageous in environments that may be subjected to significant vibration. FIG. 2B illustrates an alternate configuration of the board SSPC 10 having a different layout than the one shown in FIG. 2A. The embodiment in FIG. 2B does not include the support structure and instead includes source and drain connection terminals 44a and 44b.

The high current SSPC 10 in accordance with the present disclosure can be application specific. For example, the design can include multiple hermetic structures 36 mounted on a hermetic substrate carrier 32, where each structure can hold multiple SiC dies 34 per package. Further, the substrate 32 can accommodate multiple hermetic structures 36 yielding low forward voltage drop and low power losses of the solid-state power switching device.

For example, the SSPS dies 34, gate drives 18 and sense interfaces 20 may be arranged in groups. A first group may include a first plurality of SSPS dies 34 arranged on a first portion of the hermetic substrate 32, and a first hermetic structure 36 may be arranged over the first plurality of dies 34. A first plurality of gate drives 18 and a first plurality of sense interfaces 20 may be mounted on a first control board 38 so as to form a first HSPC 10 on the substrate 32. A second group then may include a second plurality of SSPS dies 34 arranged on a second portion of the hermetic substrate 32, and a second hermetic structure may be arranged over the second plurality of dies. A second plurality of gate drives 18 and a second plurality of sense interfaces 20 may be mounted on a second control board 38 so as to form a second HSPC 10 on the substrate 32.

Low thermal resistance can be accomplished using high thermal conductivity materials. Au/Sn can be used for the die attach and 0.020″ thick Cu/Mo composite can be used for the package electrodes/pads. Calculated thermal resistance of such an SSPC power module containing six hermetic structures each with six dies is in the order of 0.1° C./W. This allows a high power density and a large amount of safety margin in the design.

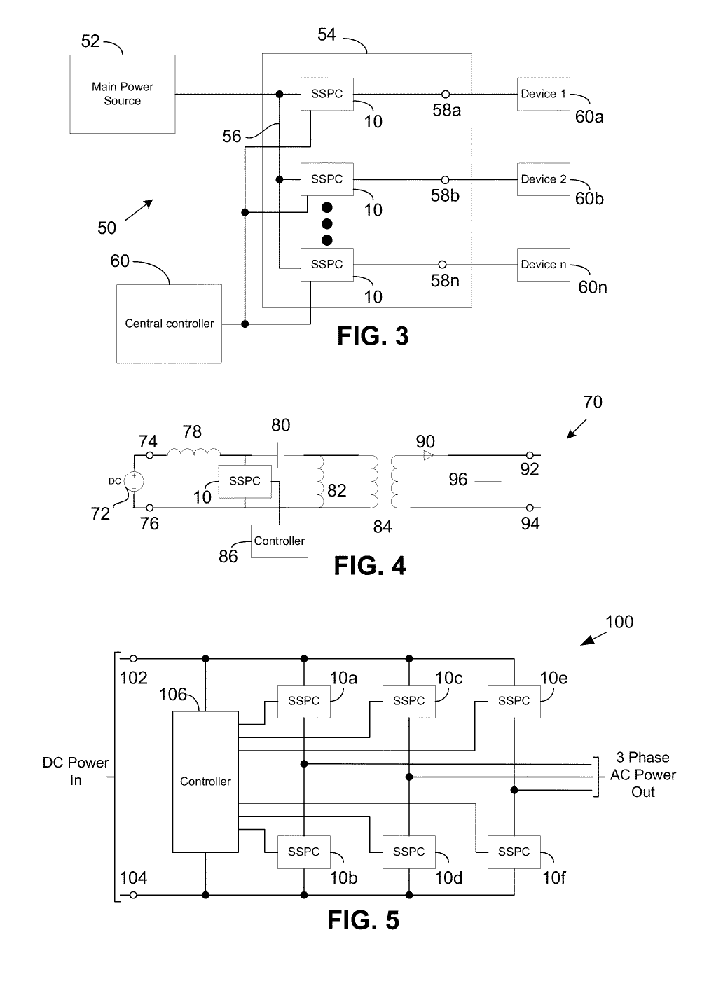

In accordance with the present disclosure, a plurality of SSPCs 10 as described herein may be utilized in a power distribution system. For example, and with reference to FIG. 3, an exemplary power distribution system 50 may include a main power source 52, which may generate power from engines of the aircraft as is conventional. The power distribution system 50 may further include power distribution panel 54 having an input bus 56 for receiving power from the power source 52, and a plurality of power output terminals 58a-58n for providing power to other devices 60a-60n (e.g., seat actuators, power outlets, aircraft lighting, etc.). A plurality of SSPCs 10 in accordance with the present disclosure are attached to the power distribution panel 54, wherein a first pole 12a of each SSPS 12 is electrically connected to the input bus 56 and a second pole 12b of each SSPS 12 is electrically connected to a respective one of the output terminals 58a-58n. The SSPCs 10 may be attached to the power distribution panel 54, for example, via fasteners, such as screws or the like. Alternatively, a cartridge assembly may be attached to the panel 54 and electrically connected to the input bus 56 and respective ones of the output terminals 58a-58n. The SSPCs 10 then may be inserted into a respective cartridge assembly so as to be electrically connected between the input bus 56 and a respective one of the output terminals 58a-58n. Such configuration is advantageous in that should an SSPC 10 fail, it can be easily replaced. Yet another mounting option would be via DIN rail or the like. A central controller 60, which may include an ASIC or a processor that executes logic stored in memory, may be communicatively coupled to each SSPC 10 and operative to selectively enable/disable each SSPC 10 so as to selectively distribute power within the aircraft. For example, the central controller 60 can communicate to each SSPC 10 via the communication interface 16b of each SSPC 10. In this manner, the central controller 60 can individually enable and disable the SSPCs 10 on the distribution panel, thereby selectively providing power to the output terminals 58a-58n. Alternatively or in additionally, each SSPC 10 may receive commands from user operated devices, e.g., a power on/off switch. Such user operated devices may be electrically connected to respective ones of the SSPCs via the I/O interface 16c as described herein.

The SSPCs 10 in accordance with the present disclosure also may be used in power conversion. For example, and with reference to FIG. 4, an exemplary DC-to-DC power converter 70 is illustrated that converts power supply from a first DC voltage (e.g., from DC power supply 72) to a second, different DC voltage.

The converter 70 includes a first terminal 74 for connecting to the positive terminal of the power supply 72, and a second terminal 76 for connecting to the negative terminal of the power supply 72. The first terminal 74 of the converter 70 is electrically connected to one leg of a first inductor 78, while a second leg of the first inductor 78 is electrically connected to a first leg of a first capacitor 80. A first pole 12a of an SSPS 12 of the SSPC 10 in accordance with the present disclosure is electrically connected between the first inductor 78 and the first capacitor 80, and a second pole 12b of the SSPS 12 is electrically connected to the second terminal 76. A second inductor 82 is electrically in parallel with a primary winding of transformer 84, and a second leg of the first capacitor 80 is electrically connected to one end of the transformer primary winding. The other end of the transformer primary winding is electrically connected to the second terminal 76. A controller 86, which may be an ASIC or a processor executing logic stored in memory, is electrically connected to the SSPC 10 and operative to control the ON/OFF switching state of the SSPS 12 within the SSPC 10.

An anode of diode 90 is connected to one leg of transformer secondary winding, and a cathode of diode 90 is connected to a first output terminal 92 of the converter 70. The other leg of the transformer secondary winding is connected to a second output terminal 94, and a filter capacitor 96 is connected in parallel between the first and second output terminals 92 and 94.

In operation, the controller 86 controls the switching of the SSPS 12 so as to apply and remove the DC voltage from the power supply 72 to the primary winding of the transformer 84. A voltage is developed on the secondary side of the transformer 84 based on the transformer turns ratio, the voltage being rectified by diode 90 and filtered by capacitor 96, thereby producing a DC voltage different from that of the power supply 72.

The SSPCs 10 in accordance with the present disclosure also may be used in power control, for example, as a power module that powers an electric motor. For example, and with reference to FIG. 5, an exemplary inverter section 100 is illustrated for providing power to a three-phase electric motor. The inverter section 100 includes first and second input terminals 102 and 104 for receiving a DC voltage. First, third and fifth SSPCs 10a, 10c and 10e in accordance with the present disclosure has a first pole 12a electrically connected to the first terminal 102, while second, fourth and sixth SSPCs 10b, 10d and 10f have a second pole electrically connected to the second terminal 104. The second pole 12b of the first SSPC 10a and the first pole of the second SSPC 10b are electrically connected to each other and form a first output phase, the second pole 12b of the third SSPC 10c and the first pole of the fourth SSPC 10d are electrically connected to each other and form a second output phase, and the second pole 12b of the fifth SSPC 10e and the first pole of the sixth SSPC 10f are electrically connected to each other and form a third output phase. A controller 106 receives power via the first and second terminals 102 and 104, and is communicatively coupled to each SSPC 10a-10f. In operation, the controller 106 selectively enables the SSPS 12 of each SSPC 10 using, for example, a pulse-width modulation (PWM) methodology so as to “invert” the DC voltage to produce a three-phase AC waveform for powering, for example, a motor as is conventional.

The solid-state power switch technology based on SiC provides an optimal solution for a high current SSPC with sufficient thermal and voltage reserve. The larger bandgap of SiC relative to Si combined with the higher electric field strength allow SiC devices to have a significant improvement in on-resistance for a given breakdown voltage. A high breakdown electric field allows the design of SiC power devices with thinner and higher-doped voltage-blocking regions and, as a consequence, a lower on-state resistance for a given breakdown voltage is achievable. The large band gap of SiC results in lower leakage currents than silicon, higher operating temperatures, higher radiation hardness, and a higher thermal conductivity.

The high current SSPC 10 in accordance with the present disclosure can utilize a high-temperature SiC Vertical Junction Field Effect Transistor (VJFET) device technology that can take full advantage of all the superior properties of SiC, and, can be scaled to meet the most demanding power switching requirements. A key parameter that enables the power scaling is the positive temperature coefficient of SiC. Devices can easily be paralleled to achieve current ratings required by high-power applications. The inherent positive temperature coefficient of resistance in the majority carrier SiC devices allows direct paralleling without the concern of thermal imbalances leading to current runaway.

The high current SSPC 10 in accordance with the present disclosure can handle the high current and/or temperature required for military and commercial aircraft applications, and provide a viable alternative to replace contactor-based distribution units while providing the reliability of solid state electronics. Further, since each electro-mechanical contactor requires separate wiring for coil excitation and power terminals, an SSPC implementation will allow weight savings in aircraft wiring. In addition, unlike classic circuit breakers, SSPCs can easily interface with TTL/CMOS signals associated with solid-state controllers, such as embedded microprocessors.

As noted above, the SSPC 10 utilizes advanced semiconductor devices to switch loads. These semiconductor devices, when switched on and off, produce heat due to the switching losses. Therefore, it is preferred to switch the semiconductors as fast as possible to reduce the switching losses, thereby reducing the heat dissipated in the semiconductor switch.

However when the semiconductors are switched at a fast rate, large voltage spikes are produced across the device. These spikes are due to the stray or leakage inductances present in the wiring and can damage the switching device if they become too large. The voltage spikes also produce electromagnetic interference (EMI) which can also interfere with the operation of other electronic devices in the system.

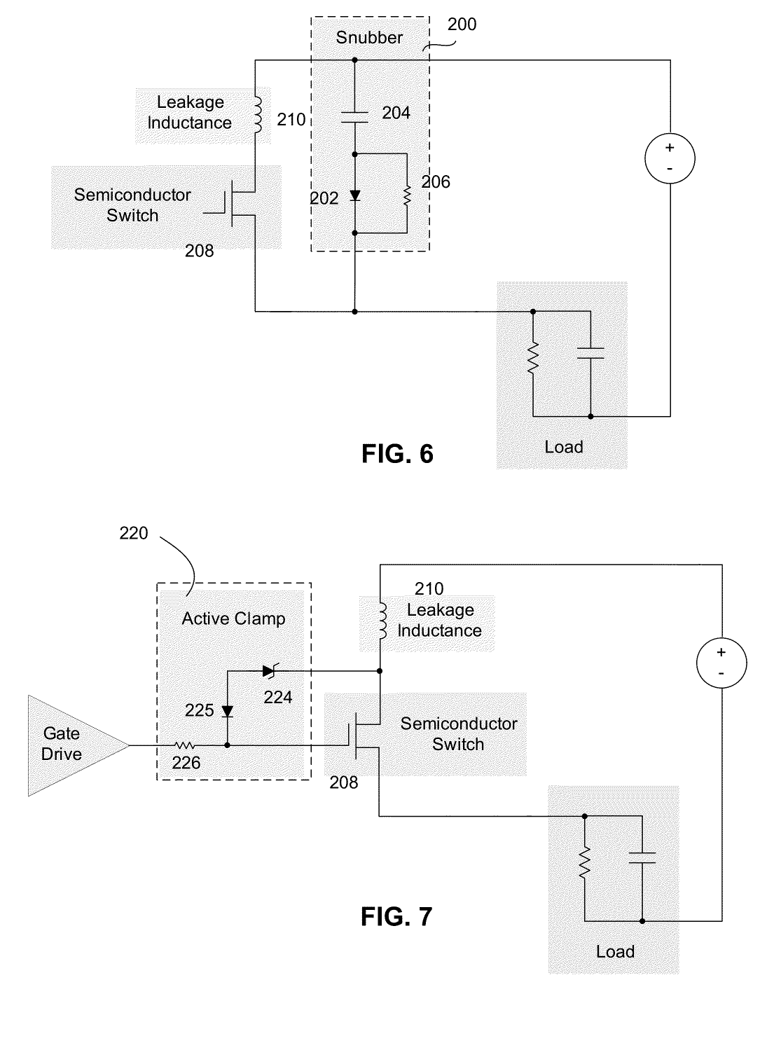

The conventional approach to minimizing the voltage spikes due to leakage inductances is the use of a snubber 200, which is shown in FIG. 6. The snubber 200 includes a diode 202, capacitor 204 and a resistor 206 which provides a means to lower the voltage spike as a result of the semiconductor switch 208 turning off, by absorbing the switching energy in the capacitor 204 and then dissipating that energy by means of the resistor 206. This approach has several draw backs. First, the snubber components are typically large in physical size and are difficult to package. Second, since all the turn off switching energy produced by the semiconductor switch is dissipated by the snubber 200 (not just the energy that can damage the semiconductor) the energy absorbed by the snubber 200 is typically much larger than is required, thereby making it inefficient. Third, since the snubber 200 is an open loop control approach, the design must be over sized for the worst case situation, which can be difficult to ascertain since the energy produced from the leakage inductances 210 cannot always be predicted or may change over time.

To efficiently protect the high current SSPC 10, an active voltage clamp can be used. The active voltage clamp provides a means to control the voltage spikes across the semiconductor switch 208 in a controlled, physically smaller, and more energy efficient manner. This is achieved by actively controlling the gate voltage of a power semiconductor switch 208 based on the voltage across the semiconductor power switch.

With reference to FIG. 7, illustrated is an exemplary active voltage clamp 220 for use with the HC SSPC 10. A semiconductor switch 208 (e.g., the HC

SSPC 10) is commanded off when a gate drive voltage decreases below a gate threshold voltage. During the turn off, the voltage across the semiconductor switch 208 may increase to a level beyond the safe operating voltage of the semiconductor switch 208 due to leakage inductances 210 in series with the switch. The active voltage clamp 220 including a transzorb (or zener diode) 224, diode 225 and impedance 226 R will actively increase the gate voltage of the semiconductor switch 208 when the voltage across the semiconductor switch 208 exceeds the breakdown voltage of the transzorb 224 connected from the drain to the gate of the semiconductor switch 208. The gate voltage increase will therefore actively clamp the voltage across the device to a predetermined maximum voltage across the semiconductor switch 208. The maximum voltage across the semiconductor switch 208 in this example is the sum of the breakdown voltage of transzorb 224 plus the gate threshold voltage of the semiconductor switch 208.

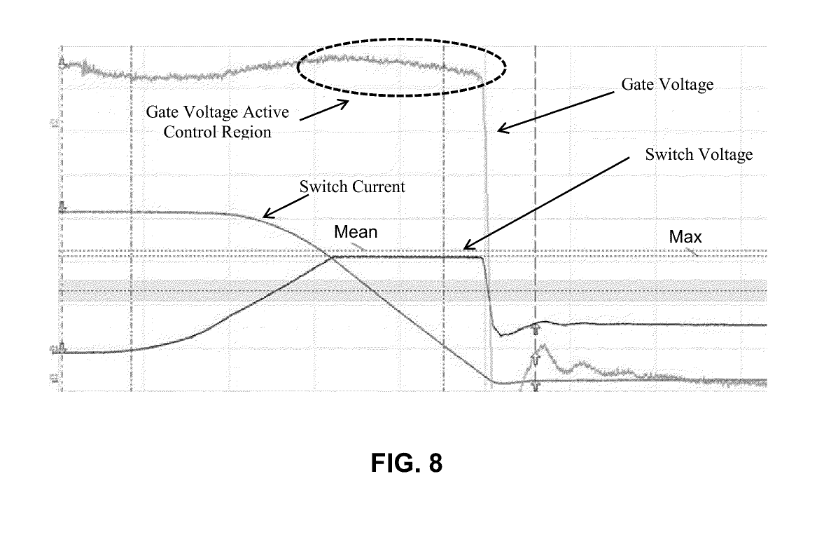

FIG. 8 shows the voltage waveforms of the active clamp 220 during a turn off. The semiconductor switch 208 is turned off by reducing the gate voltage to below the gate threshold voltage. The switch voltage will begin to rise, and the gate voltage will then plateau around the gate threshold voltage due to the inherent semiconductor Miller capacitance. The switch voltage will reach the active clamp voltage threshold and current will begin to flow into the gate via the transorb 224. The gate voltage will increase to the point at which the switch voltage is clamped to the maximum Active Clamp voltage set point. The switch voltage will remain clamped at the maximum clamp voltage until the switch current goes to zero.

The active voltage clamp 220 has several advantages in controlling the maximum switch voltage compared to using a snubber circuit 200. The active voltage clamp components are small compared to the snubber 200, only the energy that is required to keep the switch voltage at a maximum voltage is absorbed and dissipated and it is a closed loop control system allowing for dynamic changes that may occur over time or with various operating modes. The active voltage clamp also uses the semiconductor switch 208 itself to absorb and dissipate the energy from the leakage inductance. This allows utilizing the semiconductors low thermal resistance to the heat sink to provide excellent heat transfer for the dissipated energy.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A solid state power controller (SSPC), comprising:
a substrate having a plurality of regions, at least some of the plurality of regions being hermetic;
a first solid state power switch die attached directly to at least one of the hermetic regions of the substrate, the solid state power switch die including a solid state power switch having an input terminal for connecting to a power source and an output terminal for providing power to an electrical component; and
a first hermetic enclosure surrounding at least the first solid state power switch die.

2. The SSPC according to claim 1, wherein the first hermetic enclosure is arranged directly on the first solid state power switch die.

3. The SSPC according to claim 1, further comprising:
a first gate driver electrically coupled to the first solid state power switch die; and
a control module operatively coupled to the first gate driver.

4. The SSPC according to claim 1, further comprising:
a second solid state power switch die attached directly to hermetic portions of the substrate; and
a second hermetic enclosure surrounding at least the second solid state power switch die.

5. The SSPC according to claim 4, wherein the second hermetic enclosure is arranged directly on the second solid state power switch die.

6. The SSPC according to claim 4, further comprising a second gate driver coupled to the second solid state power switch die.

7. The SSPC according to claim 1, further comprising an input/output module operatively coupled to the control module.

8. The SSPC according to claim 1, further comprising a DC-DC converter operative to provide isolated power to the control module.

9. The SSPC according to claim 1, wherein the die comprises a silicon carbide transistor.

10. The SSPC according to claim 9, wherein the silicon carbide transistor comprises one of a metal oxide semiconductor field effect transistor (MOSFET), a junction gate field effect transistor (JFET) or a bipolar junction transistor (BJT).

11. The SSPC according to claim 10, wherein the JFET comprises a vertical JFET (VJFET).

12. The SSPC according to claim 1, wherein the hermetic enclosure comprises monometallic wire bonds.

13. The SSPC according to claim 1, wherein the hermetic enclosure comprises low coefficient of thermal expansion (CTE) materials.

14. The SSPC according to claim 1, wherein the substrate comprises a ceramic material.

15. The SSPC according to claim 1, wherein the substrate comprises alumina.

16. The SSPC according to claim 1, wherein the hermetic enclosure comprises copper-molybdenum.

17. The SSPC according to claim 1, further comprising electrodes electrically connected to the first solid state power switch die, the electrodes comprising copper-molybdenum.

18. The SSPC according to claim 1, wherein the first die further comprises a communication interface operative to transfer data to and receive data from another device.

19. The SSPC according to claim 1, wherein the first solid state power switch die includes a first pole for coupling to a power source and a second pole for selectively providing power from the power source to an electric device, and
further comprising a first sense interface having an input and an output, the input of the first sense interface electrically connected to second pole of the first solid state power switch, and the output of the first sense interface electrically connected to the control module.

20. The SSPC according to claim 17, wherein the first sense interface is arranged over the support structure.

21. A power distribution system, comprising:
a power source; and
a plurality of SSPC's according to claim 1, each SSPC electrically connected to the power source to selectively provide power to the respective output terminal.

22. A DC-DC converter, comprising:
first and second input terminals for receiving a DC voltage;
first and second output terminals for outputting a DC voltage;
a transformer having a primary winding and a secondary winding, the primary winding electrically connected to the first and second input terminals, and the secondary winding electrically connected to the first and second output terminals;
an SSPC according to claim 1 electrically connected to the primary winding; and
a controller operatively coupled to the SSPC, the controller operative to selectively enable and disable the SSPC to selectively apply current to the primary winding.

23. An inverter for providing an AC output voltage, comprising:
first and second input terminals for receiving a DC voltage;
a plurality of output terminals for outputting an AC voltage;
a plurality of SSPCs in accordance with claim 1, wherein a solid state power switch of a first SSPC of the plurality of SSPCs is electrically in series with a solid state power switch of a second SSPC of the plurality of SSPCs, the connection between the respective solid state power switches electrically connected to one of the plurality of output terminals, and wherein the series connected SSPCs are electrically connected to the first and second input terminals; and
a controller operatively coupled to the plurality of SSPCs, the controller configured to selectively switch the plurality of SSPCs to provide an AC output at the plurality of output terminals.
